(19) United States
(12) Patent Application Publication
(10) Pub. No.: US 2008/0001509 A1
(43) Pub. Date: Jan. 3, 2008

(54) Panel structure

(76) Inventor: Jen-Yu Wang, Chung-Ho City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/819,176

(22) Filed: Jun. 26, 2007

(30) Foreign Application Priority Data
Jun. 30, 2006 (TW) 95211546

(51) Int. Cl. H05K 5/00

(52) U.S. Cl. 312/223.2; 174/520

(57) ABSTRACT

A panel structure includes a large door and a small door. The large door and the small door can be opened and closed. The opening direction of the small door is different from that of the large door. The small door is set in a place which has a plurality of installed openings for installing any type of CD-ROM drive or hard disk. Hence, a user can assemble, disassemble, or replace a CD-ROM drive or a hard disk by simply opening the small door and without opening the large door. Therefore, it is convenient for the user to assemble, disassemble, or replace a CD-ROM drive or a hard disk, insert something into an expanded port, or press any buttons.

### BACKGROUND OF THE INVENTION

1. Field of the Invention

The present invention relates to a panel structure, and particularly relates to a panel structure having a large door and a small door.

2. Description of the Related Art

Traditional host has an openable panel for protecting any type CD-ROM drive installed hole, any type hard disk installed hole, power switch, any type expanded port, or the other function buttons. Moreover, the panel can be designed in order to produce a novel effect.

FIG. 1 shows a perspective view of a host panel structure of the prior art. The host panel structure includes a casing body 100, a panel 101, and a covering body 102. The panel 101 has a CD-ROM drive installed hole 1011, a soft disk installed hole 1012, and a plurality of buttons 1013.

However, when a user wants to assemble, disassemble, or replace a CD-ROM drive or a hard disk, insert something into an expanded port, or press buttons 1013, the covering body 102 firstly needs to be opened. Hence, it is inconvenient for users to open the covering body 102 firstly.

Moreover, users often need a larger space to open the covering body 102. Hence, the opening of the covering body 102 is limited by its external environment. Furthermore, if the user needs to use the host panel structure often, the covering body 102 must be opened every time. Hence, the covering body 102 is damaged easily by continued and frequent use.

### SUMMARY OF THE INVENTION

The first object of the present invention is to provide a panel structure. The panel structure has a large door and a small door. The large door and the small door can be opened and closed. The opening direction of the small door is different from that of the large door. The small door is set in a place which has a plurality of installed openings for installing any type of CD-ROM drive or hard disk. Hence, a user can assemble, disassemble, or replace a CD-ROM drive or a hard disk simply by opening the small door and without having to open the large door. Therefore, it is convenient for the user to assemble, disassemble, or replace a CD-ROM drive or a hard disk, insert something into an expanded port, or press any of the buttons therein.

The second object of the present invention is to provide a panel structure. When the large door is opened, the small door is opened at the same time.

The third object of the present invention is to provide a panel structure. The large door or the small door can be opened without being limited by its external environment.

A first aspect of the present invention is a panel structure, and comprises a casing body, a first door body, and a second door body. The first door body has a first pivoting portion pivoted on the casing body. The second door body has a second pivoting portion pivoted on the first door body.

A second aspect of the present invention is a panel structure, and comprises a casing body, a first doorframe, a first door body, a second doorframe, and a second door body. The first doorframe is disposed on the casing body. The first door body has a first pivoting portion pivoted on the first doorframe. The second doorframe is disposed on the first door body. The second door body has a second pivoting portion pivoted on the second doorframe.

It is to be understood that both the foregoing general description and the following detailed description are exemplary, and are intended to provide further explanation of the invention as claimed. Other advantages and features of the invention will be apparent from the following description, drawings and claims.

### BRIEF DESCRIPTION OF THE DRAWINGS

The various objects and advantages of the present invention will be more readily understood from the following detailed description when read in conjunction with the appended drawings, in which:

FIG. 1 is a perspective view of a host panel structure of the prior art;

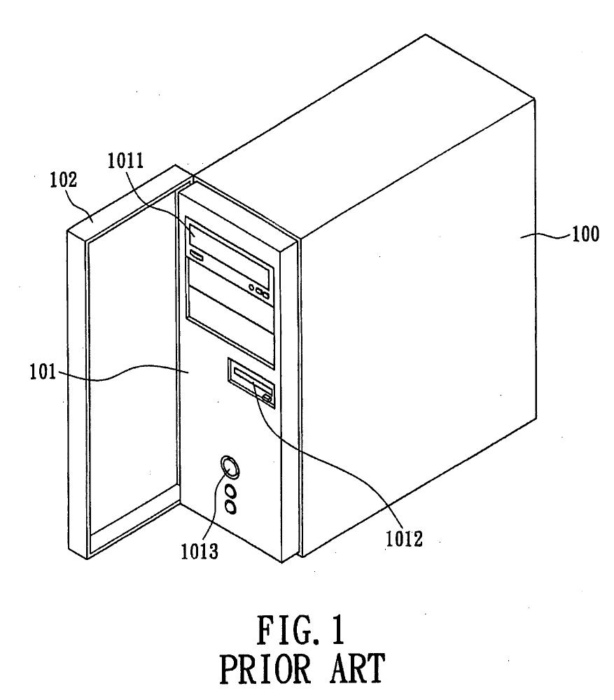

FIG. 2 is a perspective, exploded view of a panel structure according to the present invention;

FIG. 3 is a perspective, assembled view of a panel structure according to the present invention;

FIG. 4 is a perspective view of a second door body of a panel structure that has been opened independently according to the present invention;

FIG. 5 is a perspective view of a first door and a second door body of a panel structure having the same opening directions according to the present invention;

FIG. 6 is a perspective view of a first door and a second door body of a panel structure having different opening directions according to the present invention; and

FIG. 7 is a perspective, assembled view of a panel structure according to another embodiment of the present invention.

### DETAILED DESCRIPTION OF PREFERRED BEST MOLDS

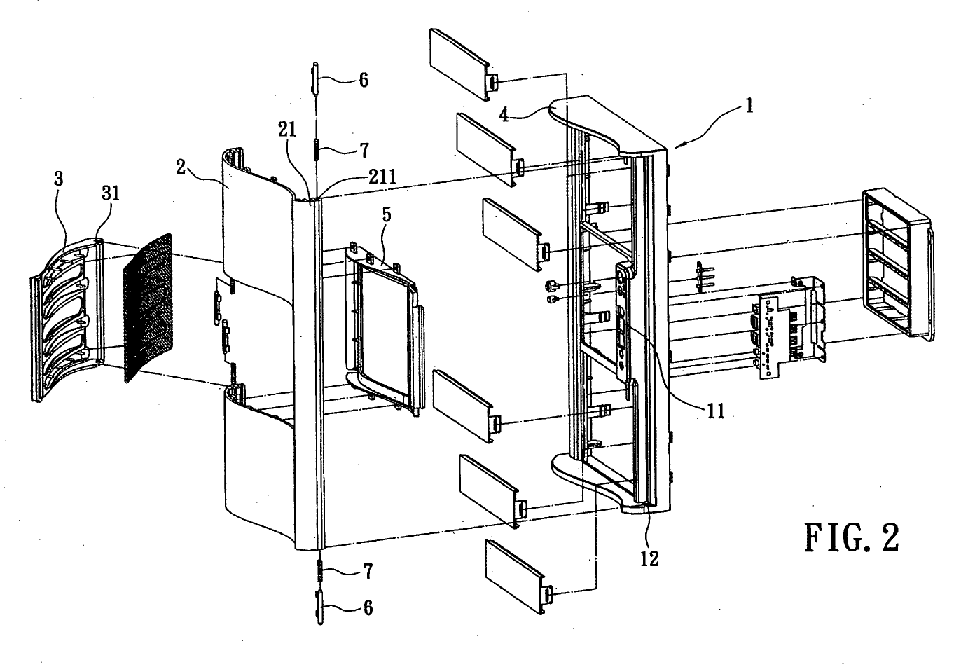

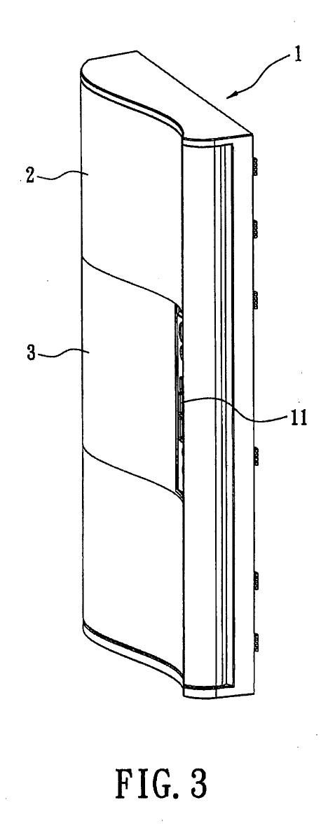

Referring to FIGS. 2 and 3, the present invention provides a panel structure that includes a casing body 1, a first door body 2, and a second door body 3. The casing body 1 is a computer casing body. The casing body 1 can be a vertical casing body or a horizontal casing body. Moreover, the casing body 1 has an expanded port 11 and two first openings 12. The expanded port 11 can be a built-in function port such as an earphone port, an USB port, or a network port, etc. The first door body 2 has a first pivoting portion 21 pivoted on the casing body 1, and the first pivoting portion 21 has two second openings 211. The second door body 3 has a second pivoting portion 31 pivoted on the first door body 2. Furthermore, the first pivoting portion 21 and the second pivoting portion 31 are pivoted on the same side of the casing body 1, or are respectively pivoted on different sides of the casing body 1. Each pair of one bolt 6 and one spring 7 is received between the corresponding first opening 12 and the corresponding second opening 211, in order to pivot the first pivoting portion 21 on the casing body 1. Hence, the first door body 2 is pivoted on the casing body 1. The second door body 3 uses the same method to pivot on the first door body 2.

The present invention provides another panel structure and includes a casing body 1, a first door body 2, a second door body 3, a first doorframe 4, and a second doorframe 5. The casing body 1 is a computer casing body. The casing body 1 can be a vertical casing body or a horizontal casing body. Moreover, the casing body 1 has an expanded port 11. The first doorframe 4 is disposed on the casing body 1. The first door body 2 has a first pivoting portion 21 pivoted on the first doorframe 4. The second doorframe 5 is disposed on the first door body 2. The second door body 3 has a second pivoting portion 31 pivoted on the second doorframe 5. Furthermore, the first pivoting portion 21 and the second pivoting portion 31 are pivoted on the same side of the casing body 1, or are respectively pivoted on different sides of the casing body 1.

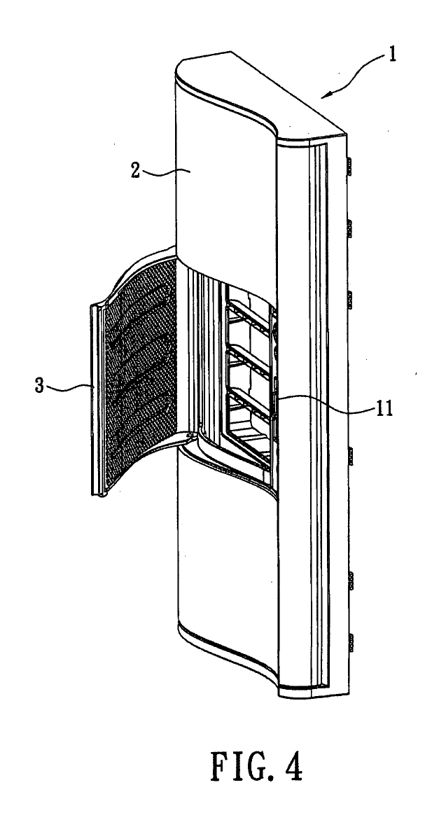

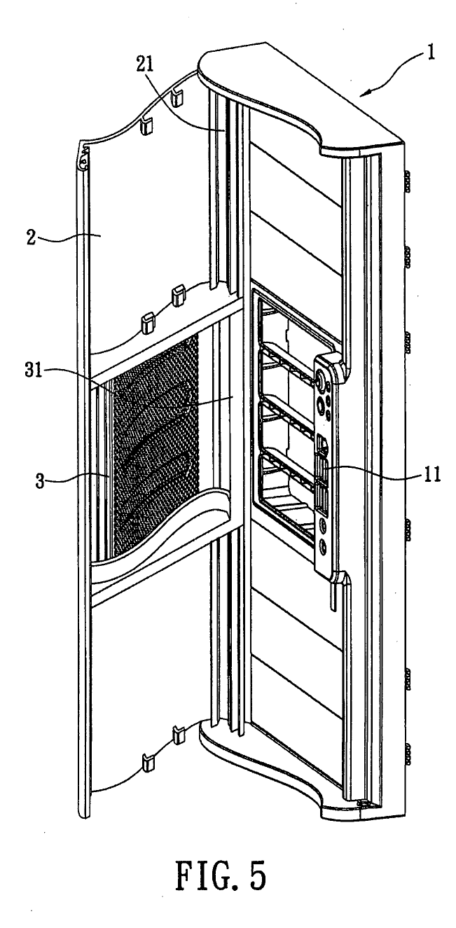

Referring to FIGS. 4 and 5, the present invention provides a panel structure. The second door body 3 can be opened independently (as shown in FIG. 4). Hence, when the second door body 3 is opened, a user can assemble, disassemble, or replace a CD-ROM drive or a hard disk without opening the first door body 2. The first door body 2 and the second door body 3 can be opened or closed. When the first door body 2 is opened, the second door body 3 is opened by the first door body 2. Furthermore, the first pivoting portion 21 and the second pivoting portion 31 are pivoted on the same side of the casing body 1. Hence, the first door body 2 and the second door body 3 have the same opening direction (as shown in FIG. 5). For example, the first door body 2 can be applied to fixed type computer hardware devices, and the second door body 3 can be applied to detachable type computer hardware devices.

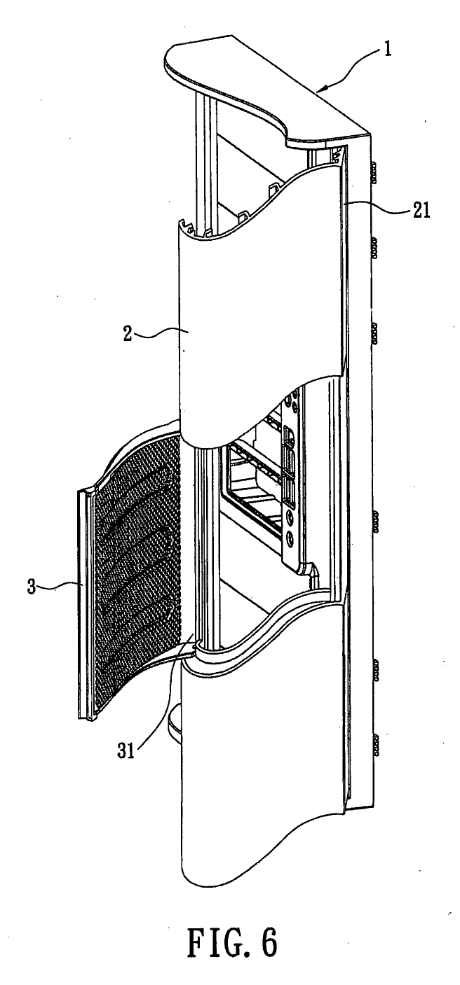

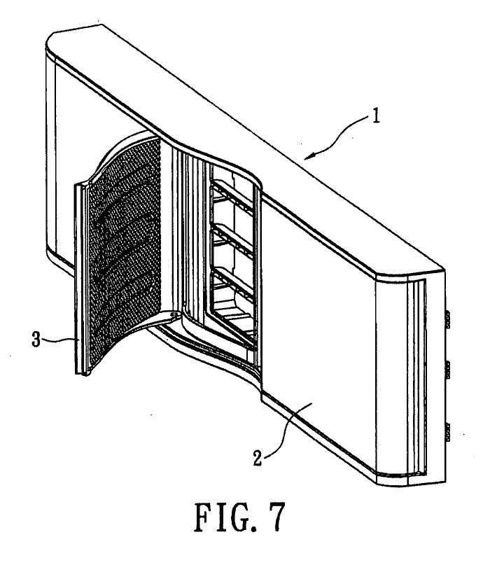

Referring to FIG. 6, the present invention provides a panel structure. The first pivoting portion 21 and the second pivoting portion 31 are respectively pivoted on different sides of the casing body 1. Hence, the first door body 2 and the second door body 3 have different opening directions. Referring to FIG. 7, the present invention provides a panel structure. The casing body 1 is a vertical casing body.

The present invention provides a panel structure that has a large door (the first door body 2) and a small door (the second door body 3). The large door and the small door can be opened and closed. An opening direction of the small door is the same as or different to that of the large door. The small door is set in a place which that has a plurality of installed openings for installing any type of CD-ROM drive or hard disk. Hence, a user can assemble, disassemble, or replace a CD-ROM drive or a hard disk by simply opening the small door and without opening the large door. Therefore, it is convenient for the user to assemble, disassemble, or replace a CD-ROM drive or a hard disk, insert something into an expanded port, or press any buttons.

Moreover, when the large door is opened, the small door is opened at the same time. The large door or the small door can be opened without being limited by the external environment.

In conclusion, the panel structure of the present invention has some advantages, as follows:

(1) The second door body 3 can be opened independently. Hence, when the second door body 3 is opened, a user can assemble, disassemble, or replace a CD-ROM drive or a hard disk without opening the first door body 2.

(2) The first door body 2 or the second door body 3 can be opened without being limited by the external environment.

(3) When the first door body 2 is opened, the second door body 3 is opened at the same time.

(4) The opening direction of the second door body 3 is the same as or different to that of the first door body 2, and can be determined according to user's need.

Although the present invention has been described with reference to the preferred best molds thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A panel structure, comprising:
a casing body;
a first door body having a first pivoting portion pivoted on the casing body; and
a second door body having a second pivoting portion pivoted on the first door body.

2. The panel structure as claimed in claim 1, wherein the casing body is a computer casing body.

3. The panel structure as claimed in claim 1, wherein the casing body is a vertical casing body.

4. The panel structure as claimed in claim 1, wherein the casing body is a horizontal casing body.

5. The panel structure as claimed in claim 1, wherein the casing body has an expanded port.

6. The panel structure as claimed in claim 1, wherein the first pivoting portion and the second pivoting portion are pivoted on the same side of the casing body.

7. The panel structure as claimed in claim 1, wherein the first pivoting portion and the second pivoting portion are pivoted on different sides of the casing body, respectively.

8. The panel structure as claimed in claim 1, wherein both the first door body and the second door body have a doorframe.

9. A panel structure, comprising:
a casing body;
a first doorframe disposed on the casing body;
a first door body having a first pivoting portion pivoted on the first doorframe;
a second doorframe disposed on the first door body; and
a second door body having a second pivoting portion pivoted on the second doorframe.

10. The panel structure as claimed in claim 9, wherein the casing body is a computer casing body.

11. The panel structure as claimed in claim 9, wherein the casing body is a vertical casing body.

12. The panel structure as claimed in claim 9, wherein the casing body is a horizontal casing body.

13. The panel structure as claimed in claim 9, wherein the casing body has an expanded port.

14. The panel structure as claimed in claim 9, wherein the first pivoting portion and the second pivoting portion are pivoted on the same side of the casing body.

15. The panel structure as claimed in claim 9, wherein the first pivoting portion and the second pivoting portion are pivoted on different sides of the casing body, respectively.
